(19) United States
(12) Patent Application Publication
(10) Pub. No.: US 2022/0068340 A1
(43) Pub. Date: Mar. 3, 2022

(54) NON-VOLATILE STATIC RANDOM ACCESS MEMORY

(71) Applicant: GLOBALFOUNDRIES U.S. Inc., Malta, NY (US)

(72) Inventors: Bipul C. Paul, Mechanicville, NY (US); Steven R. Soss, Saratoga Springs, VA (US)

(73) Assignee: GLOBALFOUNDRIES U.S. Inc., Malta, NY (US)

(21) Appl. No.: 17/007,512

(22) Filed: Aug. 31, 2020

(51) Int. Cl. G11C 11/16; G11C 7/20; G11C 5/06

(52) U.S. Cl. CPC G11C 11/1673; G11C 11/1675; G11C 5/06; G11C 11/1655; G11C 7/20; G11C 11/1657

(57) ABSTRACT

Disclosed are embodiments of a non-volatile static random access memory (NV-SRAM) cell. The NV-SRAM cell includes a static random access memory (SRAM) circuit (e.g., a conventional high performance, high reliability SRAM circuit). However, in order to avoid volatility while still retaining the advantages associated with SRAM circuit operation, the NV-SRAM cell also includes a pair of NVM circuits. These NVM circuits capture data values stored on the data nodes of the SRAM circuit prior to power down and rewrite those data values back onto the data nodes of the SRAM circuit upon power up. Also disclosed are embodiments of a method of operating a selected NV-SRAM cell in a memory array.

### BACKGROUND

### Field of the Invention

The present invention relates to non-volatile memory and, particularly, to a static random access memory (SRAM) circuit configured as a non-volatile memory.

### Description of Related Art

Static random access memories (SRAMs) are both high performance memories (i.e., characterized by fast switching speeds) and high reliability memories (i.e., characterized by a very low probability of write errors). Additionally, when SRAMs are powered on, they are considered stable because stored data is retained without requiring any refresh operation. Unfortunately, one significant disadvantage associated with SRAMs is that they are volatile. In other words, when SRAMs are powered down, stored data is lost.

### SUMMARY

In view of the foregoing, disclosed herein are embodiments of a non-volatile static random access memory (NV-SRAM) cell. The NV-SRAM cell can include a static random access memory (SRAM) circuit (e.g., a conventional high performance, high reliability SRAM circuit). However, in order to avoid volatility (i.e., to avoid losing data values stored on data nodes in the SRAM circuit when the memory array containing the memory cell is powered down) while still retaining the advantages associated with SRAM circuit operation, the NV-SRAM cell can also incorporate a pair of NVM circuits. These NVM circuits can be used to capture the data values stored on the data nodes of the SRAM circuit prior to power down and can further be used to rewrite those data values back onto the data nodes of the SRAM circuit upon power up. Also disclosed are embodiments of a method of operating a selected NV-SRAM cell in a memory array.

More particularly, disclosed herein are embodiments of a non-volatile static random access memory (NV-SRAM) cell. The NV-SRAM cell can include a static random access memory (SRAM) circuit. The NV-SRAM cell can further include a first NVM circuit, which is electrically connected to a first data node of the SRAM circuit, and a second NVM circuit, which is electrically connected to a second data node of the SRAM circuit. Also disclosed herein are embodiments of a memory array that includes multiple NV-SRAM cells, such as those described above, arranged in columns and rows.

As discussed further in the detailed description section of this specification, each such NV-SRAM cell can be configured so that, in response to a specific set of biasing conditions, a first data value stored on the first data node of the SRAM circuit and a second data value stored on the second data node of the SRAM circuit are copied into the first NVM circuit and the second NVM circuit, respectively. Copying of the first and second data values into the first and second NVM circuits can be performed, for example, just prior to powering down of the memory array so that the last stored first and second data values are captured. The first and second NVM circuits can then retain the first and second data values while the memory array is powered down. The NV-SRAM cell can further be configured so that, in response to a different set of biasing conditions, the first and second data values are rewritten from the first and second NVM circuits back onto the first and second data nodes, respectively, of the SRAM circuit. Rewriting of the first and second data values to the first and second data nodes of the SRAM circuit can be performed, for example, upon powering up of the memory array so that SRAM circuit operations using the first and/or second data values can resume.

Also disclosed herein are embodiments of a method of operating a non-volatile static random access memory (NV-SRAM) cell in a memory array, as described above.

Specifically, a method can include providing a memory array with multiple NV-SRAM cells, which are arranged in columns and rows. Each NV-SRAM cell in the memory array can include a SRAM circuit, a first NVM circuit electrically connected to a first data node of the SRAM circuit, and a second NVM circuit electrically connected to a second data node of the SRAM circuit.

The method can further include, for a selected NV-SRAM cell in the memory array, copying a first data value from the first data node of the SRAM circuit and a second data value from the second data node of the SRAM circuit into the first NVM circuit and the second NVM circuit, respectively. This process of copying the first and second data values from the first and second data nodes to the first and second NVM circuits can be achieved by applying a specific set of biasing conditions to the memory cell. Additionally, it can be performed just prior to powering down of the memory array so that the last stored first and second data values are captured and retained by the first and second NVM circuits when the memory array is powered down.

The method can further include, for the selected NV-SRAM cell, rewriting the first data value and the second data value from the first NVM circuit and the second NVM circuit back onto the first data node and the second data node, respectively, of the SRAM circuit. This process of rewriting the first and second data values to the first and second data nodes can be achieved by applying a different set of biasing conditions to the memory cell. Additionally, it can be performed upon powering up of the memory array so that SRAM circuit operations using the first and/or second data values can resume.

### BRIEF DESCRIPTION OF THE SEVERAL VIEWS OF THE DRAWINGS

The present invention will be better understood from the following detailed description with reference to the drawings, which are not necessarily drawn to scale and in which:

FIG. 1 is a schematic diagram illustrating an embodiment of a non-volatile static random access memory (NV-SRAM) cell;

FIG. 2 is a schematic diagram illustrating an embodiment of a memory array that includes multiple instances of the NV-SRAM cell of FIG. 1;

FIG. 3A is a cross-section diagram illustrating an exemplary spin transfer torque-type magnetic tunnel junctions (STT-MTJ) being programmed into the antiparallel resistance (RAP) state;

FIG. 3B is a cross-section diagram illustrating the same STT-MTJ of FIG. 3A being programmed into the parallel resistance (RP) state;

FIG. 4 is a schematic diagram illustrating another embodiment of a non-volatile static random access memory (NV-SRAM) cell;

FIG. 5 is a schematic diagram illustrating an embodiment of a memory array that includes multiple instances of the NV-SRAM cell of FIG. 4; and

FIG. 6 is a flow diagram illustrating an embodiment of a method of operating a selected NV-SRAM cell within a memory array.

### DETAILED DESCRIPTION

As mentioned above, static random access memories (SRAMs) are both high performance memories (i.e., characterized by fast switching speeds) and high reliability memories (i.e., characterized by a very low probability of write errors). Additionally, when SRAMs are powered on, they are considered stable because stored data is retained without requiring any refresh operation. Unfortunately, one significant disadvantage associated with SRAMs is that they are volatile.

In view of the foregoing, disclosed herein are embodiments of a non-volatile static random access memory (NV-SRAM) cell. The NV-SRAM cell can include a static random access memory (SRAM) circuit (e.g., a conventional high performance, high reliability SRAM circuit). However, in order to avoid volatility (i.e., to avoid losing data values stored on data nodes in the SRAM circuit when the memory array containing the NV-SRAM cell is powered down) while still retaining the advantages associated with SRAM circuit operation, the NV-SRAM cell can also incorporate a pair of NVM circuits. These NVM circuits can be used to capture the data values stored on the data nodes of the SRAM circuit prior to power down and can further be used to rewrite those data values back onto the data nodes of the SRAM circuit upon power up. Also disclosed are embodiments of a method of operating a selected NV-SRAM cell in a memory array.

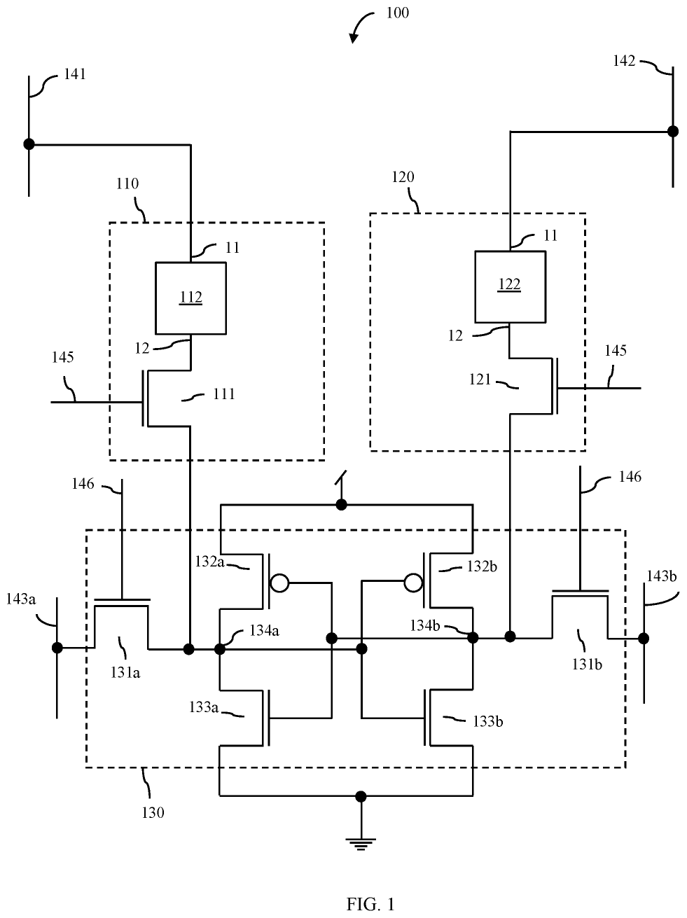

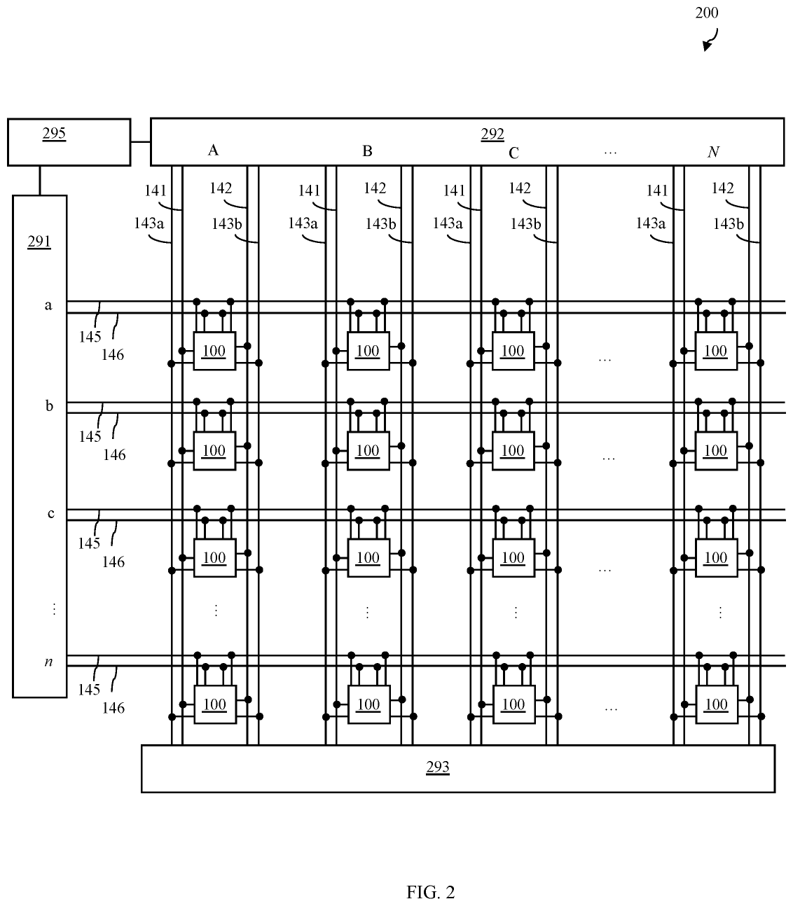

More particularly, disclosed herein are embodiments of a non-volatile static random access memory (NV-SRAM) cell 100 and of a memory array 200 that includes multiple instances of the NV-SRAM cells 100 (see FIGS. 1-2).

Specifically, as shown in FIG. 2, the memory array 200 can include multiple NV-SRAM cells 100, which are arranged in columns A-N and rows a-n.

The memory array 200 can further include a set of bitlines associated with each column. The set of bitlines can include a first NVM bitline 141, a second NVM bitline 142 and a pair of SRAM bitlines (i.e., a first SRAM bitline 143a and a second SRAM bitline 143b. Each of the bitlines in a set of bitlines associated with a specific column can be electrically connected to all of the NV-SRAM cells 100 in that specific column (as discussed in greater detail below). The memory array 200 can further include a set of wordlines associated with each row. The set of wordlines can include an NVM wordline 145 and an SRAM wordline 146. Each of the wordlines in the set of wordlines associated with a specific row can be electrically connected to all of the NV-SRAM cells 100 in that specific row (as discussed in greater detail below).

It should be understood that columns and rows refer to memory cells that are arranged essentially linearly with first parallel lines of the cells in the array being oriented in a first direction, with second parallel lines of the cells in the array oriented in a second direction that is essentially perpendicular to the first direction, and with each cell being located in both a first direction line and a second direction line. For purposes of illustration, FIG. 2 shows columns and the bitlines for the column oriented in the Y-direction and further shows the rows and the wordlines for the rows oriented in the X-direction. However, it should be understood that FIG. 2 is not intended to be limiting. For example, the columns and bitlines could be oriented in the X-direction and rows and wordlines oriented in the Y-direction.

The memory array 200 can further include a controller 295 and peripheral circuitry 291-292, which is configured to operate in response to control signals from the controller 295. Specifically, the peripheral circuitry 291 can be electrically connected to the sets of wordlines for the rows and can include, for example, address decode logic and wordline drivers for activating selected wordlines (i.e., for switching selected wordlines from low to high voltage levels) depending upon the mode of operation (as discussed below). Peripheral circuitry 292 can be electrically connected to the sets of bitlines for the columns and can include column address decode logic and bitline drivers for appropriately biasing selected bitlines depending upon the mode of operation (as discussed below). The memory array 200 can further include a sense circuit 293 configured to enable reading out of stored data. Controllers, peripheral circuitry and sense circuits employed for memory array operation are well known in the art. Thus, the details thereof have been omitted from this specification in order to allow the reader to focus on the salient aspects of the disclosed embodiments.

Each NV-SRAM cell 100 in a specific column and a specific row within the memory array 200 can include a pair of NVM circuits (i.e., a first NVM circuit 110 and a second NVM circuit 120) and also a static random access memory (SRAM) circuit 130, which has, among other components, a pair of data nodes (i.e., a first data node 134a and a second data node 134b) electrically connected to the pair of NVM circuits, as shown in FIG. 1.

Specifically, the first NVM circuit 110 can include a first access transistor 111 (e.g., an N-type field effect transistor (NFET)) and a first NVM device 112, which are connected in series between the first data node 134a of the SRAM circuit 130 and the first NVM bitline 141 for the specific column. The gate of the first access transistor 111 can be electrically connected to the NVM wordline 145 for the specific row.

The second NVM circuit 120 can include a second access transistor 121 (e.g., another N-type field effect transistor (NFET)) and a second NVM device 122, which are connected in series between the second data node 134b of the SRAM circuit 130 and the second NVM bitline 142 for the specific column. The gate of the second access transistor 121 can be electrically connected to the NVM wordline 145 for the specific row.

The first and second NVM devices 112, 122 can be, for example, two-terminal NVM devices that are programmable to either a high resistance state, which is representative of a logic value of 1, or a low resistance state, which is representative of a logic value of 0. That is, each NVM device can have a first terminal 11, which is electrically connected to an NVM bitline, and a second terminal 12, which is electrically connected to an access transistor. Furthermore, the NVM device can be configured so that, depending upon the biasing conditions applied to the two terminals 11-12 via the NVM bitline and access transistor, the resistance state can be switched from a high resistance state to a low resistance state or vice versa.

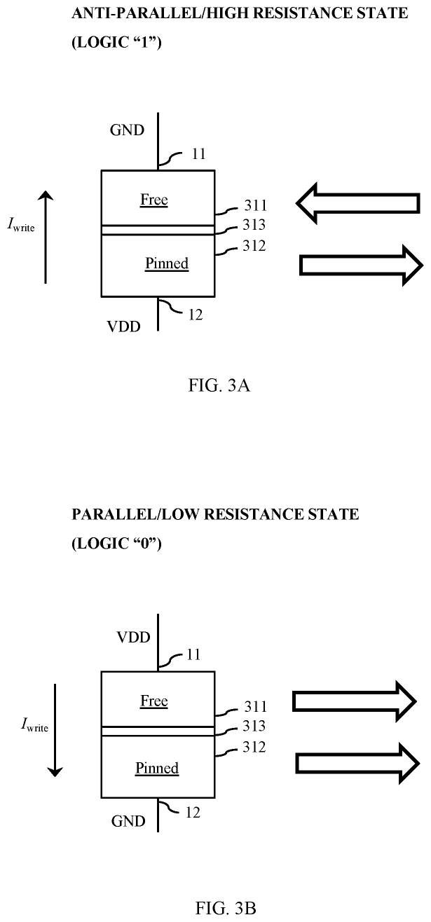

In some embodiments, the first and second NVM devices 112 and 122 can be magnetic tunnel junctions (MTJs). For example, the first and second NVM devices 112 and 122 can each be spin transfer torque-type MTJs (STT-MTJs). FIGS. 3A and 3B illustrating an exemplary STT-MTJ programmed into an anti-parallel resistance (RAP) state (also referred to herein as a high resistance state) and into a parallel resistance (RP) state (also referred to herein as a low resistance state), respectively. Those skilled in the art will recognize that an STT-MTJ is typically a back end of the line (BEOL) multi-layer structure, which includes a free ferromagnetic layer 311 (also referred to as a switchable layer or a free layer) at the first terminal 11, a pinned ferromagnetic layer 312 (also referred to as a pinned layer or a fixed layer) at the second terminal 12, and a thin dielectric layer 313 (e.g., a thin oxide layer) sandwiched between and separating the free ferromagnetic layer 311 from the pinned ferromagnetic layer 312. These layers can be configured so that the resistance state of the STT-MTJ is switchable back and forth between the RAP state (i.e., the high resistance state) and the RP state (i.e., the low resistance state) depending upon the specific biasing conditions applied to the first and second terminals 11-12. For example, a high positive voltage (VDD) could be applied to the second terminal 12 (i.e., to the pinned ferromagnetic layer 312) and the first terminal 11 could be discharged to ground (GND) (e.g., at 0V), as shown in FIG. 3A. In this case, a sufficient amount of write current (Iwrite) would flow through the device in the direction of the free ferromagnetic layer 311, thereby causing the free ferromagnetic layer 311 to switch to (or maintain) the RAP state. Alternatively, VDD could be applied to the first terminal 11 (i.e., to the free ferromagnetic layer 311) and the second terminal 12 (i.e., the pinned ferromagnetic layer 312) could be discharged to GND (e.g., at 0V), as shown in FIG. 3B. In this case, a sufficient amount of write current (Iwrite) would flow through the device in the opposite direction toward the pinned ferromagnetic layer 312, thereby causing the free ferromagnetic layer 311 to switch to (or maintain) the RP state.

Alternatively, the first and second NVM devices 112 and 122 could each be any other suitable type of two-terminal NVM device that is programmable to either a high resistance state or a low resistance state (i.e., a programmable resistor, also referred to a variable resistor).

The SRAM circuit 130 can include at least six transistors: two pass-gate transistors (e.g., two N-type field effect transistors (NFETs)); two pull-up transistors (e.g., two P-type field effect transistors (PFETs)); and two pull-down transistors (e.g., two additional NFETs). Specifically, the SRAM circuit 130 can include a first pass-gate transistor 131a and a second pass-gate transistor 131b. The SRAM circuit 130 can also include a first inverter and a second inverter, which is cross-coupled to the first inverter. The first inverter can include a first pull-up transistor 132a and a first pull-down transistor 133a connected in series between two voltage rails (e.g., VDD and GND). The drain of the first pass-gate transistor 131a can be connected to the first data node 134a, which is at the junction between the first pull-up transistor 132a and the first pull-down transistor 133a. The second inverter can include a second pull-up transistor 132b and a second pull-down transistor 133b connected in series between the two voltage rails. The drain of the second pass-gate transistor 131b can be connected to the second data node 134b, which is at the junction between the second pull-up transistor 132b and the second pull-down transistor 133b. As mentioned above, the first and second inverters can be cross-coupled and, more specifically, the gates of the first pull-up transistor 132a and the first pull-down transistor 133a can be connected to the second data node 134b and the gates of the second pull-up transistor 132b and the second pull-down transistor 133b can be connected to the first data node 134a. The source of the first pass-gate transistor 131a can be connected to the first SRAM bitline 143a for the specific column and the source of the second pass-gate transistor 131b can be connected to the second SRAM bitline 143b for the same specific column. The gates of the first and second pass-gate transistors 131a-131b can be connected to the SRAM wordline (WL) 146 for the specific row.

An NV-SRAM cell 100, which is configured as described above and incorporated into a memory array 200, can be selectively operated in any one of multiple different operating modes. Specifically, different sets of biasing conditions can be stabilized on the various bitlines and wordlines connected a selected NV-SRAM cell 100 (e.g., by the peripheral circuitry 291-292 in response to control signals from the controller 295) in order to achieve a desired function during any one of the different operating modes, as discussed below.

The operating modes of the disclosed NV-SRAM cell 100 can include conventional SRAM operating modes (i.e., a standby mode, a write mode and a read mode) during which the first and second NVM circuits 110 and 120 are disabled/inactive. The operating modes of the disclosed NV-SRAM cell 100 can also include a reset mode, a copy mode, and a rewrite mode.

More specifically, during the standby mode, the SRAM and NVM wordlines 146 and 145 can be discharged to ground (GND) (e.g., set at 0Vs) so that the first and second pass-gate transistors 131a and 131b and the first and second access transistors 111 and 121 are in an off state and, thus, so that the SRAM circuit 130 and the first and second NVM circuits 110 and 120 are idle.

During the write mode, the NVM wordline 145 can be discharged to GND so that the first and second access transistors 111 and 121 are in the off state and, thus, so that the first and second NVM circuits 110 and 120 remain idle. First and second data values can then be written to the first and second data nodes 134a-134b, respectively. It should be noted that when the first data value on the first data node 134a is a logic value of 1, the second data value on the second data node 134b will a logic value of 0 and vice versa. To write a logic value of 1 to the first data node 134a and a logic value of 0 to the second data node 134b, VDD can be applied to the first SRAM bitline 143a and the second SRAM bitline 143b can be discharged to GND. VDD can then be applied to the SRAM wordline 146 to switch the first and second pass-gate transistors 131a-134b to the on state, thereby causing the logic values of 1 and 0 to be stored on the first and second data nodes 134a-134b, respectively. To write a logic value of 0 to the first data node 134a and a logic value of 1 to the second data node 134b, the first SRAM bitline 143a can be discharged to GND and VDD can be applied to the second SRAM bitline 143b. Then, VDD can be applied to the SRAM wordline 146 in order to switch the first and second pass-gate transistors 131a-131b to the on state, thereby causing the logic values of 0 and 1 to be stored on the first and second data nodes 134a-134b, respectively.

During the read mode, the NVM wordline 145 can be discharged to GND so that the first and second access transistors 111 and 121 are in an off state and, thus, so that the first and second NVM circuits 110 and 120 remain idle. Additionally, the first and second data values can be read out by pre-charging the first and second SRAM bitlines 143a-143b to VDD. Then, VDD can be applied to the SRAM wordline 146 in order to turn on the first and second pass-gate transistors 131a-131b. When a logic value of 1 is stored on the first data node 134a and a logic value of 0 is stored on the second data value, the first SRAM bitline 143a will remain charged at its pre-charge level and the second SRAM bitline 143b will be discharged to GND through the second pass-gate transistor 131b and the second pull-down transistor 133b. Contrarily, when a logic value of 0 is stored on the first data node 134a and a logic value of 1 is stored on the second data node 134b, the second SRAM bitline 143b will remain charged at its pre-charge level and the first SRAM bitline 143a will be discharged to GND through the first pass-gate transistor 131a and the first pull-down transistor 133a. The sense circuit 293 can sense changes in electrical properties of the SRAM bitlines as an indication of the stored data.

The three conventional SRAM operating modes of the NV-SRAM cell 100 ensure that the memory array 200 has the same advantages associated with SRAMs, including high performance and high reliability. As mentioned above, in addition to these three conventional SRAM operating modes, the disclosed NV-SRAM cell 100 has three additional operating modes (i.e., the reset mode, the copy mode, and the rewrite mode).

Generally, in the reset mode, the first and second NVM devices 112 and 122 can both be reset (i.e., programmed) to the high resistance state, which as mentioned above is representative of a logic value of 1. In the copy mode, the first and second data values from the first and second data nodes 134a and 134b can be copied to the first and second NVM devices 112 and 122, respectively. Specifically, the one NVM device that is connected to the one data node storing the logic value of 0 will switch from the high resistance state (which is representative of the logic value of 1) to the low resistance state (which is representative of the logic value of 0). The other NVM device that is connected to the data node storing the logic value of 1 will remain in the high resistance state. As a result, the data values copied into the first and second NVM devices 112 and 122 will mirror the data values stored on the first and second data nodes 134a and 134b. This copy mode can be initiated, for example, by the controller 295 just prior to powering down of the memory array 200 so that the last stored first and second data values are captured. Thus, during power down, the first and second data values, which could otherwise be lost due to the volatile nature of the SRAM circuit, can be retained by the first and second NVM devices. In the rewrite mode, the first and second data values can be rewritten from the first and second NVM devices 112 and 122 back onto the first and second data nodes 134a and 134b, respectively, of the SRAM circuit 130. That is, the data values can be restored within the SRAM circuit 130. This rewrite mode can be initiated, for example, by the controller 295 upon powering up of the memory array 200 so that SRAM circuit operations using the first and/or second data values can resume.

More particularly, consider the exemplary embodiments where the first and second NVM devices 112 and 122 in the first and second NVM circuits 110 and 120 of each NV-SRAM cell 100 are STT-MTJs.

During the reset mode in a selected NV-SRAM cell, the first and second NVM devices 112 and 122 can both be reset (i.e., programmed) to the RAP state (i.e., the high resistance state, which is representative of the logic value of 1). To accomplish this, a first set of biasing conditions can be applied to the various bitlines and wordlines connected to the selected NV-SRAM cell in order to reset the first NVM device 112 to the RAP state. This first set of biasing conditions can include applying VDD to the first SRAM bitline 143a, to the SRAM wordline 146 and to the NVM wordline 145 and discharging the second SRAM bitline 143b, the first NVM bitline 141 and the second NVM bitline 142 to GND. As a result, current flows from the first SRAM bitline 143a through the first pass-gate transistor 131a and the first access transistor 111 through the first NVM device 112 in the direction of the free ferromagnetic layer 311, thereby causing the free ferromagnetic layer 311 to remain at or switch to the RAP state. Because both the second SRAM bitline 143b and the second NVM bitline 142 are at GND, current does not flow through the second NVM device 122 and the state of the second NVM device 122 remains the same. Before or after programming of the first NVM device 112 to the RAP state, a second set of biasing conditions, which is different from the first set, can be applied to the various bitlines and wordlines connected to the selected NV-SRAM cell in order to also reset the second NVM device 122 to the RAP state. This second set of biasing conditions can include applying VDD to the second SRAM bitline 143b, to the SRAM wordline 146 and to the NVM wordline 145 and discharging the first SRAM bitline 143a, the first NVM bitline 141 and the second NVM bitline 142 to GND. As a result, current flows from the second SRAM bitline 143b through the second pass-gate transistor 131b and the second access transistor 121 through the second NVM device 122 in the direction of the free ferromagnetic layer 311, thereby causing the free ferromagnetic layer 311 to remain at or switch to the RAP state. This time, because both the first SRAM bitline 143a and the first NVM bitline 141 are at GND, current does not flow through the first NVM device 112 and the first NVM device 112 remains in the RAP state.

During the copy mode in the selected NV-SRAM cell, the first and second data values from the first and second data nodes 134a and 134b can be copied from the first and second data nodes 134a and 134b to the first and second NVM devices 112 and 122, respectively. To accomplish this, a third set of biasing conditions, which is different from the first and second sets, can be applied to the various bitlines and wordlines connected to the selected NV-SRAM cell. This third set of biasing conditions can include discharging the SRAM wordline 146 to GND so as to turn off the first and second pass-gate transistors 131a and 131b of the SRAM circuit 130 and applying VDD to the NVM wordline 146 and both the first NVM bitline 141 and the second NVM bitline 142. In this case, current will only flow through the one NVM circuit that is electrically connected to the one data node on which a logic value of 0 is stored, thereby causing that NVM device to switch to the RP state (i.e., to the low resistance state, which represents the logic value of 0). For example, if the first data node 134a stores a logic value of 1 and the second data node 134b stores a logic value of 0, then under these biasing conditions current will flow from the second NVM bitline 142 (which is at VDD) through the second NVM device 122 and second access transistor 121 toward the second data node 134b, which is discharged to GND. Since, within the second NVM device 122, the current flows in the direction of the pinned ferromagnetic layer 312, the free ferromagnetic layer 311 switches to the RP state. However, because the first NVM bitline 141 and the first data node 134a are both at VDD, current does not flow through the first NVM circuit 110 and the first NVM device 112 remains in the RAP state. Alternatively, if the second data node 134b stores a logic value of 1 and the first data node 134a stores a logic value of 0, then under these same biasing conditions current will flow from the first NVM bitline 141 (which is at VDD) through the first NVM device 112 and first access transistor 111 toward the first data node 134a, which is discharged to GND. Since, within the first NVM device 112, the current flows in the direction of the pinned ferromagnetic layer 312, the free ferromagnetic layer 311 switches to the RP state. However, because the second NVM bitline 142 and the second data node 134b are both at VDD, current does not flow through the second NVM circuit 120 and the second NVM device 122 remains in RAP state. In other words, the third set of biasing conditions applied during the copy mode ensures that the data values copied to the first and second NVM devices 112 and 122 will mirror the data values stored on the first and second data nodes 134a and 134b.

During the rewrite mode in the selected NV-SRAM cell, the first and second NVM devices 112 and 122 can rewrite the first and second data values back onto the first and second data nodes 134a and 134b, respectively, of the SRAM circuit 130. To accomplish this, a fourth set of biasing conditions, which is different from the first, second and third sets, can initially be applied to the various bitlines and wordlines connected to the selected NV-SRAM cell in order to equalize the voltage levels on the first data node 134a and the second data node 134b to some specific voltage level (V_{rewrite}). V_{rewrite} can be, for example, between 0Vs and VDD (e.g., at VDD/2) but not so high as to be able to generate a sufficient current flow through the NVM devices that would result in switching of the resistance state. This fourth set of biasing conditions can include applying VDD to the SRAM wordline 146, applying V_{rewrite} to the first and second SRAM bitlines 143a and 143b, and discharging the NVM wordline 145 and the first and second NVM bitlines 141 and 142 to GND. As a result, both the first and second data nodes 134a and 134b will be pre-charged to V_{rewrite}. Next, a fifth set of biasing conditions, which is different from the first, second, third and fourth sets, can be applied to the various bitlines and wordlines connected to the selected NV-SRAM cell. This fifth set can include keeping the first and second NVM bitlines 141-142 at GND, discharging the SRAM wordline 146 to GND so as to turn off the first and second pass-gate transistors 131a and 131b of the SRAM circuit 130, and applying VDD to the NVM wordline 145 to turn on the first and second access transistors 111 and 121 of the first and second NVM circuits 110 and 120. As a result, current flows will be in the direction of the first and second NVM bitlines 141 and 142 from the first and second data nodes 134a and 134b, respectively. However, because one NVM device (i.e., the first NVM device 112 or the second NVM device 122) has the low resistance state and the other has the high resistance state following the copy mode, current flows faster through that low resistance NVM device than it does through the high resistance device. Thus, the voltage level on the data node connected to the low resistance NVM device is pulled down at a faster rate than the voltage level on the data node connected to the high resistance NVM device. Furthermore, due to cross-coupling of the inverters with the SRAM circuit 130, the lower voltage level on the data node in one inverter will cause the pull-up transistor in the opposite inverter to turn on and the pull-down transistor to turn off, thereby causing the voltage level on the other data node to be pulled up instead of down. For example, when both the first and second data nodes 134a and 134b are pre-charged to V_{rewrite}, the first NVM device 112 is in the high resistance state (which represents a logic value of 1), and the second NVM device 122 is in the low resistance state (which represents a logic value of 0), current will flow faster through that second NVM device 122 so that the second data node 134b is pulled down at a faster rate (e.g., rewriting the logic value of 0 back onto the second data node 134b). Furthermore, due to cross-coupling, the lower voltage level on this second data node 134b will turn on the first pull-up transistor 132a and turn off the first pull-down transistor 133a, thereby pulling up the voltage level on the first data node 134a (e.g., rewriting the logic value of 1 back onto the first data node 134a). Alternatively, when both the first and second data nodes 134a and 134b are pre-charged to V_{rewrite}, the first NVM device 112 is in the low resistance state (which represents a logic value of 0), and the second NVM device 122 is in the high resistance state (which represents a logic value of 1), current will flow faster through that first NVM device 112 so that the first data node 134a is pulled down at a faster rate (e.g., to rewrite the logic value of 0 back onto the first data node 134a). Furthermore, due to cross-coupling, the lower voltage level on this first data node 134a will turn on the second pull-up transistor 132b and turn off the second pull-down transistor 133b, thereby pulling up the voltage level on the second data node 134b (e.g., to rewrite the logic value of 1 back onto the second data node 134b).

As mentioned above, the copy mode can be initiated by the controller 295 just prior to powering down of the memory array 200 so that the last stored first and second data values are captured in the first and second NVM devices 112 and 122 of the first and second NVM circuits 110 and 120. This ensures that, during power down, the first and second data values, which would otherwise be lost due to the volatility of the SRAM circuit, continue to be stored. Additionally, the rewrite mode can be initiated by the controller 295 upon powering up of the memory array 200 so that SRAM circuit operations using the first and/or second data values can resume. The reset mode can initially be performed prior to any data storage in the SRAM circuit 130. Additionally, the reset mode must be repeated between completion of each rewrite mode and initiation of the next copy mode because the first and second NVM devices 112 and 122 must both be in the high resistance state for the copying function to work as described above. However, during the reset mode, the first and second data values currently stored on the first and second data nodes can be lost. This is because the first set of biasing conditions result in the first data node being charged to VDD and the second data node being discharged to GND and the second set of biasing conditions result in the first data node being discharged to GND and the second data node being charged to VDD. To protect against data loss during the reset mode, the reset mode could be triggered only when the currently stored first and second data values are deemed unnecessary or obsolete (e.g., as indicated by a flag) and performed prior to the next write mode when new first and second data values are to be written onto the first and second data nodes 134a and 134b. Alternatively, to protect against data loss during the reset mode, a standard architectural approach could be employed. For example, each reset mode could be preceded by temporary storage of the current first and second data values in temporary buffers and followed by restoration of those first and second data values.

In the embodiment of the NV-SRAM cell 100 described above and illustrated in FIG. 1, the SRAM circuit 130 has six transistors. Specifically, it is shown as being a 6T SRAM circuit with a single read/write port through which read and write operations are performed. However, it should be noted that, optionally, the SRAM circuit 130 of the NV-SRAM cell 100 could have more than six transistors for multiple ports through which read and/or write operations could be performed. Those skilled in the art will recognize that multi-port SRAMs allow two accesses of either the same memory cell or different memory cells in the same row or in different rows to occur during the same clock cycle (i.e., during the same access period).

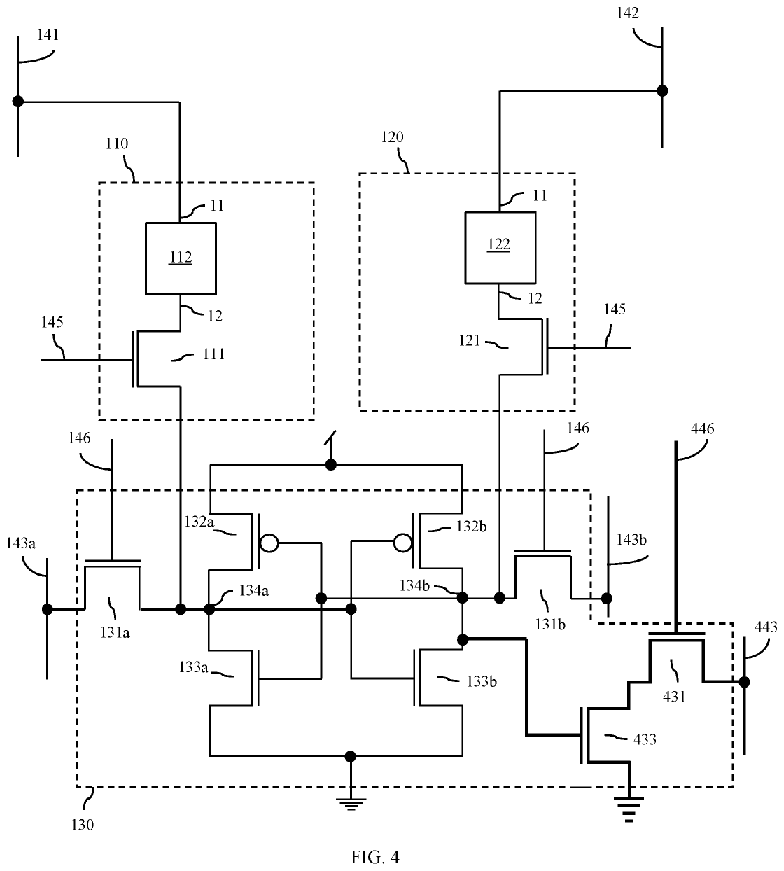

For example, as illustrated in FIG. 4, the SRAM circuit 130 could alternatively include the six transistors discussed above plus two additional transistors such that it is an eight-transistor (8T) SRAM circuit with a read/write port and a read only port. The two additional transistors could include an additional pass-gate transistor 431 (e.g., an additional NFET) and an additional pull-down transistor 433 (e.g., another additional NFET), which are connected in series between an additional SRAM bitline 443 and GND. The gate of the additional pull-down transistor 433 can be electrically connected to the second data node 134b and the gate of the additional pass-gate transistor 431 can be electrically connected to an additional SRAM wordline 446. Such an SRAM circuit can enable read/write operations through one port via the first and second pass-gate transistors 131a and 131b, as discussed in detail above as well as single-ended read operations through another port via the additional pass-gate transistor 431. During a single-ended read operation, the first and second NVM circuits 110 and 120 can be inactive/disabled. The additional SRAM bitline 443 can be pre-charged to VDD and VDD can be applied the additional SRAM wordline 446 to turn on the additional pass-gate transistor 431. If the second data value stored on the second data node 134b is a logic value of 0, then, during the single-ended read operation, the voltage level on the second data node 134b will be pulled down and the additional pull-down transistor 433 will remain off so that the additional SRAM bitline 443 is not discharged. Contrarily, if the second data value stored on the second data node is a logic value of 1, then, during the single-ended read operation, the voltage level on second data node 134b will be pulled up and the additional pull-down transistor 433 will turn on so that the additional SRAM bitline 443 is discharged to GND through the additional pass-gate transistor 431 and the additional pull-down transistor 433. With such an 8T-SRAM circuit, the additional SRAM wordline 446 can be discharged to GND so that the additional pass-gate transistor 431 is in the off state during the above-discussed reset, copy and rewrite operations.

Alternatively, the SRAM circuit 130 could include the six transistors discussed above plus four additional transistors such that it is a ten-transistor (10T) SRAM circuit so as to have two read/write ports (not shown). Alternatively, the SRAM circuit 130 could have any other SRAM configuration that includes at least the six transistors, discussed above, with the first and second data nodes 134a and 134b, which are located at the junctions between pull-up and pull-down transistors in a pair of cross-coupled first and second inverters and which are electrically connected to first and second NVM circuits 110 and 120, respectively.

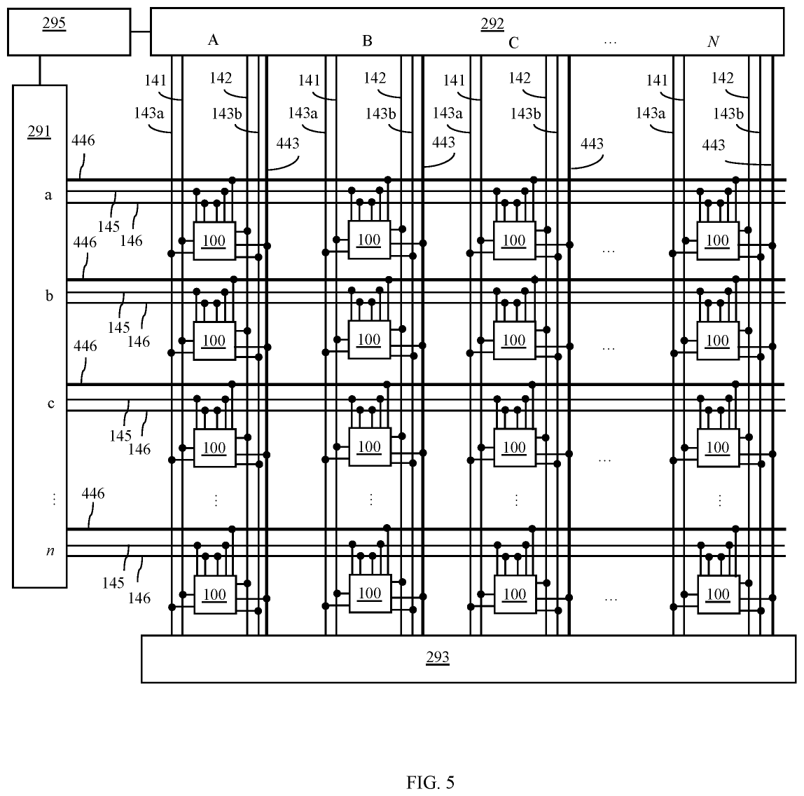

It should be noted that if the SRAM circuit 130 in each NV-SRAM cell 100 includes additional transistors for additional port(s) (e.g., as discussed above and shown in FIG. 4). The memory array 200 can further include the additional bitline(s) and wordline(s) to support read and/or write operations using the additional port(s). For example, as illustrated in FIG. 5, if the SRAM circuit 130 in each NV-SRAM cell 100 includes eight transistors (e.g., is an 8T-SRAM circuit, as shown in FIG. 4), then the set of bitlines for each column of the NV-SRAM cells 100 can further include an additional SRAM bitline 443 and the set of wordlines for each row can further include an additional SRAM wordline 446. Furthermore, the peripheral circuitry 291 and 292 can be configured to selectively bias the additional bitlines and wordlines in response to control signals from the controller 295 and the sense circuit 293 can be configured to perform any required sense operations.

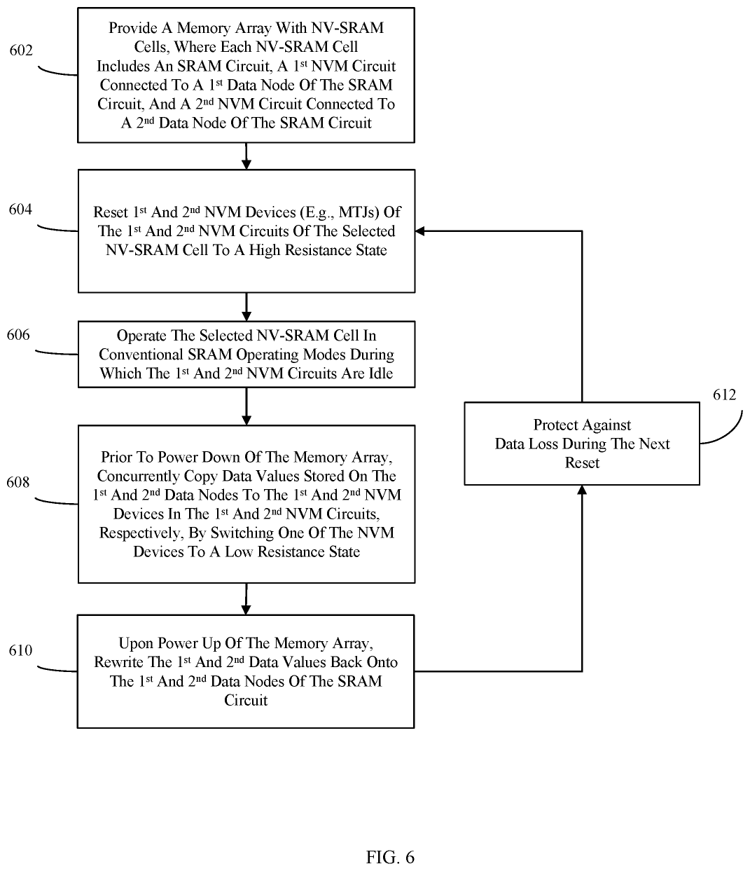

Referring to the flow diagram of FIG. 6, also disclosed herein embodiments of a method of operating a selected NV-SRAM cell 100 within a memory array 200, as described in detail above and illustrated in FIGS. 1-2.

Specifically, the method can include providing a memory array, such as the memory array 200 described in detail above and shown in FIG. 2, and powering on the memory array 200 (see process step 602). The memory array 200 can include multiple NV-SRAM cells 100, which are arranged in columns and rows. Each NV-SRAM cell 100 can include a SRAM circuit 130, a first NVM circuit 110 electrically connected to a first data node 134a of the SRAM circuit 130, and a second NVM circuit 120 electrically connected to a second data node 134b of the SRAM circuit 130, as described in detail above and shown in FIG. 1.

The method can include, while the memory array is powered on, resetting the first and second NVM devices 112 and 122 to the high resistance state, which as mentioned above is representative of a logic value of 1 (see process step 604). For example, consider the exemplary embodiments where the first and second NVM devices 112 and 122 are STT-MTJs. To reset the first and second NVM devices 112 and 122 to the RAP state (i.e., the high resistance state, which is representative of the logic value of 1), VDD can be applied to the first SRAM bitline 143a, to the SRAM wordline 146 and to the NVM wordline 145 and the second SRAM bitline 143b, the first NVM bitline 141 and the second NVM bitline 142 can be discharged to GND. As a result, current flows from the first SRAM bitline 143a through the first pass-gate transistor 131a and the first access transistor 111 through the first NVM device 112 in the direction of the free ferromagnetic layer 311, thereby causing the free ferromagnetic layer 311 to remain at or switch to the RAP state. Because both the second SRAM bitline 143b and the second NVM bitline 142 are at GND, current does not flow through the second NVM device 122 and the state of the second NVM device 122 remains the same. Before or after resetting of the first NVM device 112 to the RAP state, VDD can also be applied to the second SRAM bitline 143b, to the SRAM wordline 146 and to the NVM wordline 145 and the first SRAM bitline 143a, the first NVM bitline 141 and the second NVM bitline 142 can be discharged to GND. As a result, current flows from the second SRAM bitline 143b through the second pass-gate transistor 131b and the second access transistor 121 through the second NVM device 122 in the direction of the free ferromagnetic layer 311, thereby causing the free ferromagnetic layer 311 to remain at or switch to the RAP state. This time, because both the first SRAM bitline 143a and the first NVM bitline 141 are at GND, current does not flow through the first NVM device 112 and the first NVM device 112 remains in the RAP state.

It should be noted that timing of this resetting process step is discussed in greater detail below at process step 612.

The method can further include, while the memory array is powered on, operating the selected NV-SRAM cell 100 in one or more of the conventional SRAM operating modes (i.e., a standby mode, a write mode and a read mode) during which the first and second NVM circuits 110 and 120 are disabled/inactive (i.e., idle) (see process step 606). The processes employed during conventional standby, write and read operating modes of SRAM circuits are well known in the art and are also described in detail above with regard to the structure embodiments.

The method can further include, immediately prior to powering down the memory array 200 and after the first and second NVM devices 112 and 122 have been reset, copying the first and second data values from the first and second data nodes 134a and 134b to the first and second NVM devices 112 and 122, respectively (see process step 608). During this copying process, the one NVM device that is connected to the one data node storing the logic value of 0 will switch from the high resistance state (which is representative of the logic value of 1) to the low resistance state (which is representative of the logic value of 0). The other NVM device that is connected to the data node storing the logic value of 1 will remain in the high resistance state. As a result, the data values copied into the first and second NVM devices 112 and 122 will mirror the data values stored on the first and second data nodes 134a and 134b. For example, consider the exemplary embodiments where the first and second NVM devices 112 and 122 are STT-MTJs. To copy the first and second data values from the first and second data nodes 134a and 134b to the first and second NVM devices 112 and 122, the SRAM wordline 146 can be discharged to GND so as to turn off the first and second pass-gate transistors 131a and 131b of the SRAM circuit 130 and VDD can be applied to the NVM wordline 146 and to both the first NVM bitline 141 and the second NVM bitline 142. In this case, current will only flow through the one NVM circuit that is electrically connected to the one data node on which a logic value of 0 is stored, thereby causing that one NVM device to switch to the RP state (i.e., to the low resistance state, which represents the logic value of 0). As a result, the copy mode ensures that the data values copied to the first and second NVM devices 112 and 122 mirror the data values stored on the first and second data nodes 134a and 134b. Thus, during power down, the first and second data values, which could otherwise be lost due to the volatile nature of the SRAM circuit, can be retained by the first and second NVM devices.

The method can further include, upon powering up of the memory array, rewriting the first and second data values from the first and second NVM devices 112 and 122 of the first and second NVM circuits 110 and 120 back onto the first and second data nodes 134a and 134b, respectively, of the SRAM circuit 130 (see process step 610). For example, consider the exemplary embodiments where the first and second NVM devices 112 and 122 are STT-MTJs. To rewrite the first and second data values back onto the first and second data nodes 134a and 134b, respectively, of the SRAM circuit 130, the voltage levels on the first data node 134a and the second data node 134b must first be equalized to some specific voltage level (V_{rewrite}). V_{rewrite} can be, for example, between 0V and VDD (e.g., at VDD/2) but not so high as to be able to generate a sufficient current flow through the NVM devices that would result in switching of the resistance state. To set both the first and second data nodes 134a and 134b at V_{rewrite}, VDD can be applied to the SRAM wordline 146, V_{rewrite} can be applied to the first and second SRAM bitlines 143a and 143b, and the NVM wordline 145 and the first and second NVM bitlines 141 and 142 can be discharged to GND. As a result, both the first and second data nodes 134a and 134b will be pre-charged to V_{rewrite}. Next, the first and second NVM bitlines 141-142 can be kept at GND, the SRAM wordline 146 can be discharged to GND so as to turn off the first and second pass-gate transistors 131a and 131b of the SRAM circuit 130, and VDD can be applied to the NVM wordline 145 to turn on the first and second access transistors 111 and 121 of the first and second NVM circuits 110 and 120. As a result, current flows will be in the direction of the first and second NVM bitlines 141 and 142 from the first and second data nodes 134a and 134b, respectively. However, because one NVM device (i.e., the first NVM device 112 or the second NVM device 122) will be a low resistance NVM device and the other will be a high resistance device following the copying process, current flow through the low resistance NVM device will be faster than current flow through the high resistance NVM device. Thus, the voltage level on the data node connected to the low resistance device will be pulled down at a faster rate than the voltage level on the data node connected to the high resistance NVM device. Additionally, due to cross-coupling of the inverters within the SRAM circuit 130, when the voltage level on one data node within one inverter is pulled down at a faster rate, it will cause the pull-up transistor in the opposite inverter to turn on and the pull-down transistor in the opposite inverter to turn off, thereby causing the voltage level on the opposite data node connected to high resistance NVM device to be pulled up instead of down. Thus, the voltage levels on the first and second data nodes 134a and 134b, following the rewrite process, will mirror the stored data from the first and second NVM devices 112 and 122.

As mentioned above, the copying at process step 608 can be initiated just prior to powering down of the memory array 200 so that the last stored first and second data values are captured in the first and second NVM devices 112 and 122. This ensures that, during power down, the first and second data values, which would otherwise be lost due to the volatility of the SRAM circuit, continue to be stored. Additionally, the rewriting at process step 610 can be initiated upon powering up of the memory array 200 so that SRAM circuit operations using the first and/or second data values can resume. The resetting at process step 604 can initially be performed prior to any write operations in the SRAM circuit 130. Additionally, the resetting must be repeated between completion of each rewrite mode and initiation of the next copy mode because the first and second NVM devices 112 and 122 must both be in the high resistance state for the copying process to work as described above. However, during the resetting process, the first and second data values currently stored on the first and second data nodes can be lost. Thus, the method can further include, prior to repeating the resetting process, protecting against data loss (see process step 612). For example, the resetting process could be triggered (e.g., by a flag) only when the currently stored first and second data values are deemed unnecessary or obsolete and further performed prior to the next write operation during which new first and second data values are to be written onto the first and second data nodes 134a and 134b. Alternatively, the resetting process could be preceded by temporary storage of the first and second data values in temporary buffers and followed by restoration of those first and second data values.

It should be understood that the terminology used herein is for the purpose of describing the disclosed structures and methods and is not intended to be limiting. For example, as used herein, the singular forms “a”, “an” and “the” are intended to include the plural forms as well, unless the context clearly indicates otherwise. Additionally, as used herein, the terms “comprises” “comprising”, “includes” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right”, “left”, “vertical”, “horizontal”, “top”, “bottom”, “upper”, “lower”, “under”, “below”, “underlying”, “over”, “overlying”, “parallel”, “perpendicular”, etc., are intended to describe relative locations as they are oriented and illustrated in the drawings (unless otherwise indicated) and terms such as “touching”, “in direct contact”, “abutting”, “directly adjacent to”, “immediately adjacent to”, etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A memory cell comprising:
a static random access memory circuit comprising a first data node and a second data node;
a first non-volatile memory circuit electrically connected in series between the first data node and a first non-volatile memory bitline, wherein the first non-volatile memory circuit comprises: a first access transistor connected to the first data node; and a first two-terminal non-volatile memory device connected between the first access transistor and the first non-volatile memory bitline; and
a second non-volatile memory circuit electrically connected in series between the second data node and a second non-volatile memory bitline, wherein the second non-volatile memory circuit comprises: a second access transistor connected to the second data node; and a second two-terminal non-volatile memory device connected between the second access transistor and the second non-volatile memory bitline.

2. The memory cell of claim 1,
wherein the memory cell is configured to enable a first data value from the first data node and a second data value from the second data node to be copied into the first non-volatile memory circuit and the second non-volatile memory circuit, respectively, so as to retain the first data value and the second data value when a memory array containing the memory cell is powered down, and
wherein the memory cell is further configured to enable the first data value and the second data value to be rewritten from the first non-volatile memory circuit and the second non-volatile memory circuit back to the first data node and the second data node, respectively, upon powering up of the memory array.

3. The memory cell of claim 1, wherein, within the memory cell, when the first access transistor of the first non-volatile memory circuit and the second access transistor of the second non-volatile memory circuit are in off states, the first two-terminal non-volatile memory device is electrically isolated from the first data node, the second two-terminal non-volatile memory device is electrically isolated from the second data node, and the static random access memory circuit is operable in read, write, and standby modes.

4. The memory cell of claim 1, wherein gates of the first access transistor and the second access transistor are electrically connected to a same non-volatile memory wordline.

5. The memory cell of claim 1, wherein the first two-terminal non-volatile memory device and the second two-terminal non-volatile memory device comprise spin transfer torque-type magnetic tunnel junctions and wherein each spin transfer torque-type magnetic tunnel junction comprises a free ferromagnetic layer at a first terminal electrically connected to a corresponding non-volatile memory bitline, a fixed ferromagnetic layer at a second terminal electrically connected to a corresponding access transistor, and a dielectric layer between the free ferromagnetic layer and the fixed ferromagnetic layer.

6. The memory cell of claim 1, wherein the static random access memory circuit comprises a six-transistor static random access memory cell comprising:
a first inverter comprising: a first pull-up transistor and a first pull-down transistor electrically connected in series, wherein the first data node is at a first junction between the first pull-up transistor and the first pull-down transistor;
a second inverter cross-coupled with the first inverter and comprising: a second pull-up transistor and a second pull-down transistor electrically connected in series, wherein the second data node is at a second junction between the second pull-up transistor and the second pull-down transistor;
a first pass-gate transistor electrically connected in series between a first static random access memory bitline and the first data node; and
a second pass-gate transistor electrically connected in series between a second static random access memory bitline and the second data node.

7. The memory cell of claim 6, wherein gates of the first pass-gate transistor and the second pass-gate transistor are electrically connected to a same static random access memory wordline.

8. The memory cell of claim 1, wherein the static random access memory circuit comprises more than six transistors.

9. A memory array comprising:
memory cells arranged in columns and rows, wherein each memory cell comprises:
a static random access memory circuit electrically connected to a first static random access memory bitline for a specific column containing the memory cell and to a second static random access memory bitline for the specific column, wherein the static random access memory circuit comprises a first data node and a second data node;
a first non-volatile memory circuit electrically connected in series between the first data node and a first non-volatile memory bitline of the specific column, wherein the first non-volatile memory circuit comprises: a first access transistor connected to the first data node; and a first two-terminal non-volatile memory device connected between the first access transistor and the first non-volatile memory bitline for the specific column; and
a second non-volatile memory circuit electrically connected in series between the second data node and a second non-volatile memory bitline for the specific column, wherein the second non-volatile memory circuit comprises: a second access transistor connected to the second data node; and a second two-terminal non-volatile memory device connected between the second access transistor and the second non-volatile memory bitline for the specific column,
wherein each memory cell is configured to enable a first data value from the first data node and a second data value from the second data node to be copied into the first non-volatile memory circuit and the second non-volatile memory circuit, respectively, so as to retain the first data value and the second data value when the memory array is powered down, and
wherein each memory cell is further configured to enable the first data value and the second data value to be rewritten from the first non-volatile memory circuit and the second non-volatile memory circuit back to the first data node and the second data node, respectively, upon powering up of the memory array.

10. The memory array of claim 9, further comprising:
static random access memory wordlines for the rows, wherein each row of the memory cells has a corresponding static random access memory wordline electrically connected to the static random access memory circuit of each memory cell in the row;
non-volatile memory wordlines for the rows, wherein each row of the memory cells has a corresponding non-volatile memory wordline electrically connected to the first non-volatile memory circuit and to the second non-volatile memory circuit of each memory cell in the row;
pairs of static random access memory bitlines for the columns, wherein each column of the memory cells has a corresponding pair of static random access memory bitlines electrically connected to the static random access memory circuit of each memory cell in the column;
first non-volatile memory bitlines for the columns, wherein each column of the memory cells has a corresponding first non-volatile memory bitline electrically connected to the first non-volatile memory circuit of each memory cell in the column; and
second non-volatile memory bitlines for the columns, wherein each column of the memory cells has a corresponding second non-volatile memory bitline electrically connected to the second non-volatile memory circuit of each memory cell in the column.

11. The memory array of claim 9, wherein, within each memory cell, when the first access transistor of the first non-volatile memory circuit and the second access transistor of the second non-volatile memory circuit are in off states, the first two-terminal non-volatile memory device is electrically isolated from the first data node, the second two-terminal non-volatile memory device is electrically isolated from the second data node, and the static random access memory circuit is operable in read, write, and standby modes.

12. The memory array of claim 9, wherein, in each memory cell, gates of the first access transistor and the second access transistor are electrically connected to a non-volatile memory wordline of a specific row containing the memory cell.

13. The memory array of claim 9, wherein, in each memory cell, the first two-terminal non-volatile memory device and the second two-terminal non-volatile memory device comprise spin transfer torque-type magnetic tunnel junctions and wherein each spin transfer torque-type magnetic tunnel junction comprises a free ferromagnetic layer at a first terminal electrically connected to a corresponding non-volatile memory bitline, a fixed ferromagnetic layer at a second terminal electrically connected to a corresponding access transistor, and a dielectric layer between the free ferromagnetic layer and the fixed ferromagnetic layer.

14. The memory array of claim 9, wherein, in each memory cell, the static random access memory circuit comprises a six-transistor static random access memory circuit comprising:
a first inverter comprising: a first pull-up transistor and a first pull-down transistor electrically connected in series, wherein the first data node is at a first junction between the first pull-up transistor and the first pull-down transistor;
a second inverter cross-coupled with the first inverter and comprising: a second pull-up transistor and a second pull-down transistor electrically connected in series, wherein the second data node is at a second junction between the second pull-up transistor and the second pull-down transistor;
a first pass-gate transistor electrically connected in series between the first static random access memory bitline of the specific column containing the memory cell and the first data node; and
a second pass-gate transistor electrically connected in series between the second static random access memory bitline for the specific column and the second data node.

15. The memory array of claim 14, wherein, in each memory cell, gates of the first pass-gate transistor and the second pass-gate transistor are electrically connected to a static random access memory wordline for a specific row containing the memory cell.

16. The memory array of claim 9, wherein, in each memory cell, the static random access memory circuit comprises more than six transistors.

17. A method comprising:
selecting a memory cell in a memory array, wherein the memory array comprising memory cells arranged in columns and rows, and wherein each memory cell comprises:
a static random access memory circuit electrically connected to a first static random access memory bitline for a specific column containing the memory cell and to a second static random access memory bitline for the specific column, wherein the static random access memory circuit comprises a first data node and a second data node;
a first non-volatile memory circuit electrically connected in series between the first data node and a first non-volatile memory bitline for the specific column, wherein the first non-volatile memory circuit comprises: a first access transistor connected to the first data node and a first two-terminal non-volatile memory device connected between the first access transistor and the first non-volatile memory bitline for the specific column; and
a second non-volatile memory circuit electrically connected in series between the second data node and a second non-volatile memory bitline for the specific column wherein the second non-volatile memory circuit comprises: a second access transistor connected to the second data node and a second two-terminal non-volatile memory device connected between the second access transistor and the second non-volatile memory bitline for the specific column;
in the selected memory cell in the memory array, copying a first data value from the first data node and a second data value from the second data node into the first non-volatile memory circuit and the second non-volatile memory circuit, respectively; and
in the selected memory cell, rewriting the first data value and the second data value from the first non-volatile memory circuit and the second non-volatile memory circuit back to the first data node and the second data node, respectively.

18. The method of claim 17,
wherein, within each memory cell, the first two-terminal non-volatile memory device and the second two-terminal non-volatile memory device are programmable so as to have one of a first resistance that is representative of a logic value of 1 and a second resistance that is less than the first resistance and representative of a logic value of 0,
wherein, within each memory cell, gates of the first access transistor and the second access transistor are electrically connected to a non-volatile memory wordline for a specific row containing the memory cell,
wherein, within each memory cell, the static random access memory circuit comprises: a static random access memory cell comprising: a first pass-gate transistor electrically connected in series between the first static random access memory bitline for the specific column and the first data node; and a second pass-gate transistor electrically connected in series between the second static random access memory bitline for the specific column and the second data node, and
wherein gates of the first pass-gate transistor and the second pass-gate transistor are electrically connected to a static random access memory wordline for the specific row.

19. The method of claim 18, further comprising, in the selected memory cell, resetting the first two-terminal non-volatile memory device and the second two-terminal non-volatile memory device to the first resistance, wherein the copying switches to the second resistance the one of the first two-terminal non-volatile memory device and the second two-terminal non-volatile memory device that is connected to the one of the first data node and the second data node storing the logic value of 0.

20. The method of claim 19,
wherein the copying is performed at power down of the memory array to ensure that the first data value and the second data value are retained,
wherein the rewriting is performed upon power up of the memory array, and
wherein the resetting is performed prior to the copying and requires protection against unwanted data loss.
